(19) United States
(12) Patent Application Publication
(10) Pub. No.: US 2015/0171052 A1
(43) Pub. Date: Jun. 18, 2015

(54) SUBSTRATE OF SEMICONDUCTOR AND METHOD FOR FORMING THE SAME

(71) Applicant: Chung-Shan Institute of Science and Technology, Armaments Bureau, M.N.D, Taoyuan County (TW)

(72) Inventors: Yang-Kuao Kuo, Taoyuan County (TW); Cheng-Hung Shih, Taoyuan County (TW); Jian-Long Ruan, Taoyuan County (TW); Lea-Hwung Leu, Taoyuan County (TW)

(73) Assignee: Chung-Shan Institute of Science and Technology, Armaments Bureau, M.N.D, Taoyuan County (TW)

(21) Appl. No.: 14/133,366

(22) Filed: Dec. 18, 2013

(51) Int. Cl. H01L 23/00

(52) U.S. Cl. CPC H01L 24/83; H01L 24/27; H01L 2224/8384; H01L 2924/10323; H01L 2924/12041; H01L 2224/2745; H01L 2224/27462; H01L 2924/2064; H01L 2924/20644; H01L 2924/20645; H01L 2924/20646; H01L 2924/20647; H01L 2924/201; H01L 2224/2908; H01L 2224/29147; H01L 2224/29166; H01L 2224/29184

(57) ABSTRACT

A substrate of semiconductor is formed by a method including preparing two aluminum nitride (AlN) substrates; forming a first buffer layer on a surface of each AlN substrate; forming a second buffer layer on a free surface of each first buffer layer; and providing an oxygen free copper (OFC) layer to be securely sandwiched between the second buffer layers through a sintering process. Said substrate is a sandwiched structure and is able to be directly carried out coating process to grow semiconductor device thereon.

### BACKGROUND OF THE INVENTION

1. Field of the Invention

The present invention relates to a substrate of semiconductor and a method for forming the same, and more particularly to a sandwiched structure of aluminum nitride (AlN)/copper/AlN as well as the fabrication method thereof.

2. Description of the Related Art

The heat dissipation is quite important in LED device, because most energy is transferred to heat rather than light illuminating, and if the heat accumulates too much in the circuit, the efficiency of the LED device may be greatly influenced. In general, the heat may be dissipated through (1) air, (2) a substrate connecting to a circuit board and (3) electrode wires connecting to the circuit board.

Substrate of semiconductor plays an important role in heat dissipation, it functions as a medium connecting the die and the circuit board. Most substrate is made of ceramic substrate, and depending on the wiring design of semiconductor, the substrate can be formed in particular scales.

However, for a well known printing method of forming lines or patterns on the substrate in high temperature co-fired ceramic (HTCC) or low temperature co-fired ceramic (LTCC) technique, the precision of the lines and patterns is not enough for the requirement as the entire scale of semiconductor device is forced to be reduced.

### SUMMARY OF THE INVENTION

The objective of the present invention is to provide a substrate of semiconductor and a method for forming the same, and the surface of the substrate can be directly processed with electroplating for forming lines and patterns, which greatly improves the precision of structure even the device scale is reduced.

In order to achieve the foregoing purpose, the method including following steps: preparing two aluminum nitride (AlN) substrates; forming a first buffer layer on a surface of each AlN substrate; forming a second buffer layer on a free surface of each first buffer layer; and providing an oxygen free copper (OFC) layer to be securely sandwiched between the second buffer layers through a sintering process. For lattice match between layers, titanium or wolfram and copper are selected to be said buffer layers. According to aforementioned steps, the final product is a sandwich-structured substrate, and is able to be directly carried out coating process to grow semiconductor device thereon, which is not able to be achieved in HTCC and LTCC techniques.

### BRIEF DESCRIPTION OF THE DRAWINGS

The invention, as well as its many advantages, may be further understood by the following detailed description and drawings in which:

FIG. 1 is a flow chart showing a method for forming a substrate in accordance with the present invention; and

FIG. 2 is an exploded view of the substrate structure formed according to the method of FIG. 1.

### DETAILED DESCRIPTION OF THE INVENTION

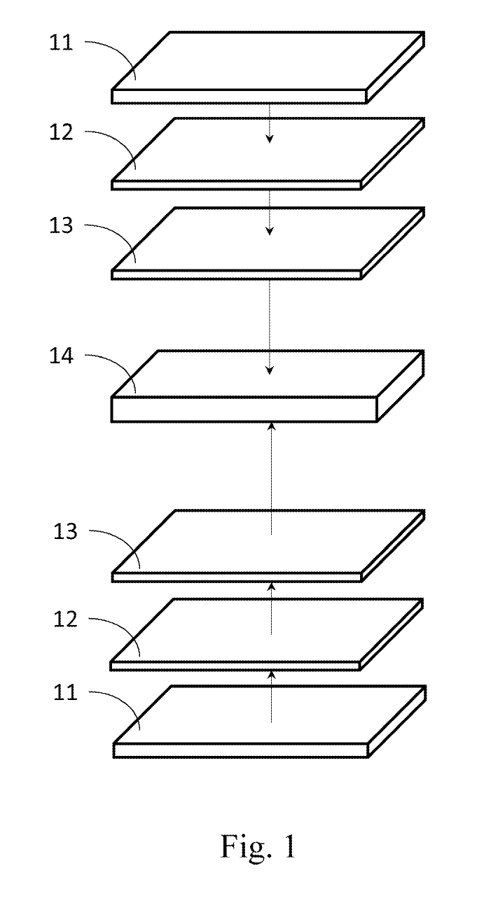

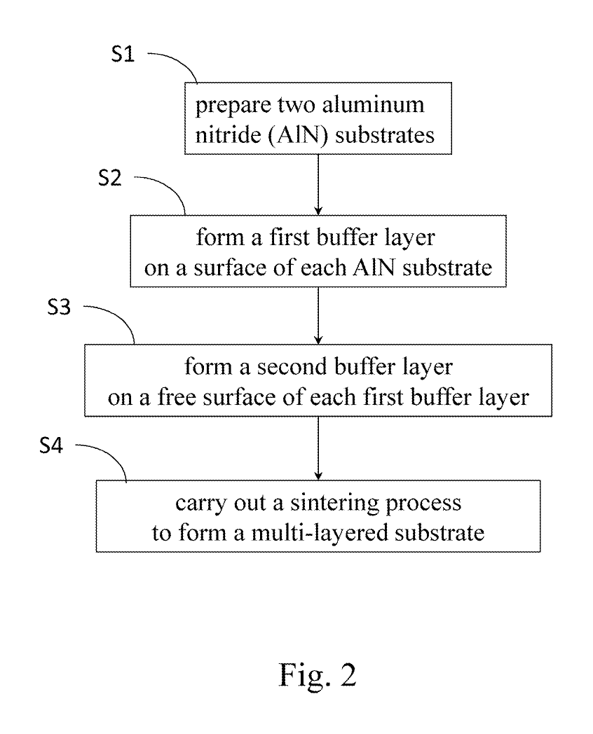

With reference to both FIGS. 1-2, illustrating a method for forming a substrate of semiconductor in accordance with the present invention has steps S1-4.

Step S1: prepare two aluminum nitride (AlN) substrates 11 cutting from a block. The thickness of the AlN substrate 11 is in arrange of 0.38-0.5 mm, and the scales of the AlN substrates 11 can be the same or different depending on the design purpose.

Step S2: form a first buffer layer 12 on a surface of each AlN substrate with the use of sputtering. The first buffer layer 12 is made of titanium or wolfram, and the thickness of the first buffer layer 12 is controlled in a range of 1-2 μm.

Step S3: form a second buffer layer 13 on a free surface of each first buffer layer 12 with the use of electroplating. The second buffer layer 13 is made of copper, and the thickness of the second buffer is controlled in a range of 20-28 μum.

Step S4: carry out a sintering process to form a multi-layered substrate. Provides an oxygen free copper (OFC) layer 14 sandwiched between the second buffer layers 13, and the thickness of the OFC layer 14 is in a range of 0.4-0.7 mm. Put the sandwiched structure into a chamber of an atmosphere furnace to be sealed and heated at a sintering temperature of a range of 900-1050° C., while passing nitrogen gas into the chamber to insulate the sandwiched structure from air causing chemical reactions. After a period time of sintering, the second buffer layers 13 are securely jointed to the OFC layer 14 and forming the multi-layered substrate.

In Summary, the method of foregoing Steps S1-4 independently forms the substrate, and both sides of the substrate are AlN which is able to be carried out further coating to grow additional semiconductor structures thereon, which can be applied into scale-reduced electric devices, such as high power LED and high density integrated circuit.

Many changes and modifications in the above described embodiment of the invention are able to, of course, be carried out without departing from the scope thereof. Accordingly, to promote the progress in science and the useful arts, the invention is disclosed and is intended to be limited only by the scope of the invention.

What is claimed is:

1. A method for forming a substrate of semiconductor comprising steps of:
preparing two aluminum nitride (AlN) substrates;
forming a first buffer layer on a surface of each AlN substrate;
forming a second buffer layer on a free surface of each first buffer layer; and
providing an oxygen free copper (OFC) layer to be securely sandwiched between the second buffer layers through a sintering process.

2. The method for forming a substrate of semiconductor as claimed in claim 1, wherein the first buffer layer is made of titanium or wolfram by sputtering process, and the thickness thereof is in a range of 1-2 μm.

3. The method for forming a substrate of semiconductor as claimed in claim 2, wherein the second buffer layer is made of copper by electroplating process, and the thickness thereof is in a range of 20-28 μm.

4. The method for forming a substrate of semiconductor as claimed in claim 2, wherein the thickness of the OFC layer is in a range of 0.4-0.7 mm.

5. The method for forming a substrate of semiconductor as claimed in claim 3, wherein the thickness of the OFC layer is in a range of 0.4-0.7 mm.

6. The method for forming a substrate of semiconductor as claimed in claim 4, wherein the sintering process provides a sintering temperature in a range of 900-1050° C.

7. The method for forming a substrate of semiconductor as claimed in claim 5, wherein the sintering process provides a sintering temperature in a range of 900-1050° C.
